(19) United States
(12) Patent Application Publication
(10) Pub. No.: US 2025/0323073 A1
(43) Pub. Date: Oct. 16, 2025

(54) ELECTRONIC DEVICE FOR SUPPORTING ANALYSIS OF SEMICONDUCTOR PROCESS FLOW AND AN OPERATING METHOD OF THE ELECTRONIC DEVICE

(71) Applicant: SAMSUNG ELECTRONICS CO., LTD., Suwon-si (KR)

(72) Inventors: YOUNGKWAN KIM, Suwon-si (KR); EUISEOK KUM, Suwon-si (KR); Sanghyuck KIM, Suwon-si (KR); YIJEONG KIM, Suwon-si (KR); CHANGOH PARK, Suwon-si (KR); EDWARD SUNG, Suwon-si (KR); EUN YOUNG LEE, Suwon-si (KR); BORA JEONG, Suwon-si (KR); SUNGMIN CHO, Suwon-si (KR); YUNHYEOK JO, Suwon-si (KR)

(21) Appl. No.: 19/047,750

(22) Filed: Feb. 7, 2025

(30) Foreign Application Priority Data
Apr. 16, 2024 (KR) 10-2024-0050855

(51) Int. Cl. H01L 21/67

(52) U.S. Cl. CPC H01L 21/67276; H01L 21/67288

(57) ABSTRACT

An operating method for an electronic device including a processor for analyzing a semiconductor process flow, the method including: receiving process entry data for a plurality of wafers; extracting process sequence data that enumerates processes related to the plurality of wafers in order of execution times, based on the process entry data; selecting an analysis target parameter from among process parameters included in the process entry data; sorting the process entry data based on the process sequence data and the analysis target parameter; and mapping the sorted process entry data to a parallel coordinate system to generate analysis data, wherein the analysis data includes time information related to the processes in the process sequence data and wafer-specific process flow information corresponding to the analysis target parameter.

### CROSS-REFERENCE TO RELATED APPLICATION

This application claims priority under 35 U.S.C. § 119 to Korean Patent Application No. 10-2024-0050855, filed on Apr. 16, 2024, in the Korean Intellectual Property Office, the disclosure of which is incorporated by reference herein in its entirety.

### TECHNICAL FIELD

Embodiments of the present disclosure described herein relate to an electronic device, and more particularly, to an electronic device that supports the analysis of a semiconductor process flow for a plurality of wafers and an operating method thereof.

### DISCUSSION OF RELATED ART

Semiconductor devices are manufactured through multiple processes. As semiconductor design technology advances, the number of manufacturing processes and their complexity increase. With the growing number of processes and the heightened complexity of each, various defects may arise during the manufacturing of semiconductor devices.

When a defect occurs, a process flow analysis can be conducted to compare process performance histories of a normal wafer and a defective wafer. This analysis helps identify any abnormal sections within the process. To facilitate the detection of these abnormal sections, a method for visualizing the process performance history is required.

### SUMMARY

Embodiments of the present disclosure provide an electronic device designed to support the analysis of a semiconductor process flow, enabling more efficient analysis, along with an operating method of the electronic device.

According to an embodiment of the present disclosure, there is provided an operating method for an electronic device including a processor for analyzing a semiconductor process flow, the method including: receiving, at the processor, process entry data for a plurality of wafers; extracting, at the processor, process sequence data that enumerates processes related to the plurality of wafers in order of execution times, based on the process entry data; selecting, at the processor, an analysis target parameter from among process parameters included in the process entry data; sorting, at the processor, the process entry data based on the process sequence data and the analysis target parameter; and mapping, at the processor, the sorted process entry data to a parallel coordinate system to generate analysis data, wherein the analysis data includes time information related to the processes in the process sequence data and wafer-specific process flow information corresponding to the analysis target parameter.

According to an embodiment of the present disclosure, there is provided an electronic device for analyzing a semiconductor process flow, including: a processor; and a memory configured to store process entry data for a plurality of wafers, wherein the processor is configured to execute a module to: extract process sequence data in which processes associated with the plurality of wafers are listed in order of their execution times based on the process entry data; select an analysis target parameter from among process parameters included in the process entry data; sort the process entry data based on the process sequence data and the analysis target parameter; and generate analysis data by mapping the sorted process entry data to a parallel coordinate system, wherein the analysis data includes time information associated with the processes in the process sequence data and wafer-specific process flow information associated with the analysis target parameter.

According to an embodiment of the present disclosure, there is provided an electronic device including: a memory configured to store process entry data for a plurality of wafers; a data extractor configured to extract process sequence data that lists processes related to the plurality of wafers in order of their execution times based on the process entry data; a data sorter configured to select an analysis target parameter from among process parameters included in the process entry data and to sort the process entry data based on the process sequence data and the analysis target parameter; and a data mapper configured to generate analysis data by mapping the sorted process entry data to a parallel coordinate system, wherein the analysis data includes time information related to the processes in the process sequence data and wafer-specific process flow information related to the analysis target parameter.

### BRIEF DESCRIPTION OF THE DRAWINGS

The above and other features of the present disclosure will become apparent by describing in detail embodiments thereof with reference to the accompanying drawings.

FIG. 1 illustrates a system for analyzing a semiconductor process flow according to an embodiment of the present disclosure.

FIG. 2 is a block diagram illustrating an electronic device according to an embodiment of the present disclosure.

FIG. 3 illustrates an example of an operating method of an electronic device.

FIG. 4 illustrates an example of process entry data according to an embodiment of the present disclosure.

FIG. 5 illustrates an example of process sequence data according to an embodiment of the present disclosure.

FIG. 6 illustrates an example of sorted process entry data according to an embodiment of the present disclosure.

FIG. 7 illustrates an example of analysis data according to an embodiment of the present disclosure.

FIG. 8 illustrates a first node of FIG. 7 in detail.

FIG. 9 is a block diagram illustrating an electronic device according to an embodiment of the present disclosure.

### DETAILED DESCRIPTION OF THE EMBODIMENTS

Hereinafter, embodiments of the present disclosure will be described clearly and in detail, enabling a person skilled in the relevant technical field to easily practice these embodiments.

Components referenced by terms such as “part or unit”, “module”, “block”, and suffixes like “˜or/˜er” in the detailed description, as well as functional blocks illustrated in the drawings, may be implemented as software, hardware, or a combination thereof. For example, the software may be machine code, firmware, embedded code, and application software. For example, the hardware may include an electrical circuit, an electronic circuit, a processor, a computer, an integrated circuit, integrated circuit cores, a pressure sensor, an inertial sensor, a microelectromechanical system (MEMS), a passive element, or a combination thereof.

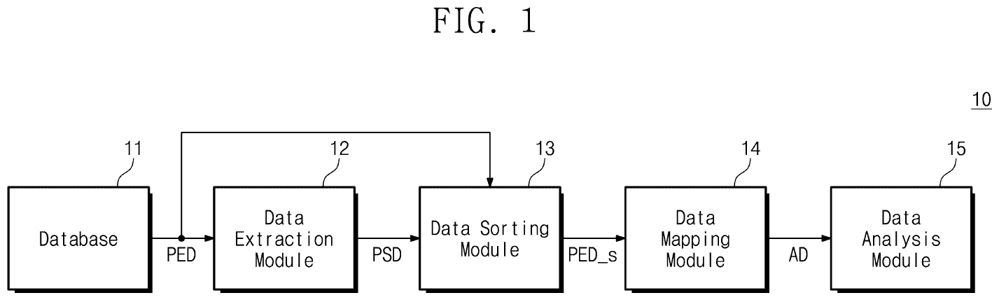

FIG. 1 illustrates a system 10 for analyzing a semiconductor process flow according to an embodiment of the present disclosure. Referring to FIG. 1, the system 10 may include a database 11, a data extraction module 12, a data sorting module 13, a data mapping module 14, and a data analysis module 15.

The database 11 may store process entry data PED including a plurality of process history data PHD. The process history data PHD may include various information related to a process. For example, each of process history data PHD may include information such as a wafer on which the process was performed, a type of process performed, classification names of process parameters related to the process, and process execution times.

The process parameters may represent technical elements related to the process. For example, the process parameters may include details about a facility used in the process, a recipe applied to the process, a reticle applied to the process, and the like.

Each classification name of the process parameters may correspond to a name of technical element. For example, the classification names representing facilities may correspond to names of the facilities, and the classification names representing the recipes may correspond to names of the recipes. In an embodiment, at least some of the plurality of process history data PHD may be related to a restoration process. The restoration process refers to returning the wafer to its state before a specific process is performed.

The data extraction module 12 may receive the process entry data PED from the database 11. The data extraction module 12 may extract process sequence data PSD that lists the processes performed on a plurality of wafers in order of their execution times, based on the process entry data PED. For example, the data extraction module 12 may extract the process sequence data PSD that enumerates all the processes performed on the plurality of wafers in sequence according to their execution times, based on the process entry data PED.

The data extraction module 12 may arrange the processes in the process sequence data PSD based on their execution times, assigning a higher priority to processes with earlier execution times. For example, the data extraction module 12 may assign the highest priority to the process that was performed first in the process sequence data PSD.

In one embodiment, some of the processes in the process sequence data PSD may be duplicated. For example, if a particular process is performed twice on a specific wafer, the particular process may be listed (e.g., enumerated) twice in the process sequence data PSD.

In an embodiment, if some of the processes in the process sequence data PSD are duplicated, the process sequence data PSD may include a restoration process listed between the duplicated processes. For example, if a second process is performed twice on a first wafer, the process sequence data PSD may include the restoration process inserted between two instances of the second process.

The data sorting module 13 may receive the process entry data PED from the database 11. The data sorting module 13 may select an analysis target parameter ATP among process parameters included in the process entry data PED. For example, the data sorting module 13 may allow a user to select one of the process parameters included in the process entry data PED as the analysis target parameter ATP.

The data sorting module 13 may receive the process sequence data PSD from the data extraction module 12. The data sorting module 13 may sort the process entry data PED based on the analysis target parameter ATP and the process sequence data PSD. For example, the data sorting module 13 may sort the plurality of process history data PHD in the process entry data PED for each wafer, based on the analysis target parameter ATP and the process sequence data PSD.

Specifically, the data sorting module 13 may sort the process entry data PED so that each of the plurality of process history data PHD in the process entry data PED corresponds to each wafer and each process of the process sequence data PSD based on the analysis target parameter ATP. Sorted process entry data PED_s may express the plurality of process history data PHD as classification names of the analysis target parameter ATP. In other words, the data sorting module 13 may sort (e.g., organize) the process entry data PED so that each of classification names of the analysis target parameter ATP representing the plurality of process history data PHD corresponds to each wafer and each process of the process sequence data PSD.

As a result of the sorting, the plurality of process history data PHD, represented by the classification names of the analysis target parameter ATP, may be listed for each wafer in the sorted process entry data PED_s. In addition, the plurality of process history data PHD, expressed by the classification names of the analysis target parameter ATP, may be arranged according to a process order of the process sequence data PSD in the sorted process entry data PED_S.

In an embodiment, some of the fields in the sorted process entry data PED_s may not correspond to the process history data PHD. For example, some of the processes in the process sequence data PSD may not be carried out on a specific wafer. In this case, the fields in the sorted process entry data PED_s corresponding to these processes and wafers can be assigned values indicating the absence of a process history. For example, when a first process of the process sequence data PSD is not performed on the first wafer, the value of the field in the first process and the sorted process entry data PED_s corresponding to the first wafer may be “N/A” or “NULL”.

In an embodiment, a process may be listed twice within the process sequence data PSD, and performed fewer than two times on a specific wafer. In this case, unless there is an issue with the process history of that wafer, the process history data PHD related to the wafer and the repeated process may be sorted to correspond to the instance of the process with a higher priority in the process sequence data PSD.

The data mapping module 14 may receive the sorted process entry data PED_s from the data sorting module 13. The data mapping module 14 may generate analysis data AD by mapping the sorted process entry data PED_s to a first coordinate system. The analysis data AD may be simulation data obtained by mapping the sorted process entry data PED_s to the first coordinate system. In an embodiment, the first coordinate system may be a parallel coordinate system.

The analysis data AD may include first elements, second elements, and third elements. In an embodiment, the first element may be a dimension axis, the second element may be a node, and the third element may be a connection line.

The data mapping module 14 may map the processes of the process sequence data PSD to the first elements, respectively, based on the sorted process entry data PED_s. As a result of the mapping, the processes of the process sequence data PSD may correspond to the first elements, respectively.

The data mapping module 14 may map classification names of the sorted process entry data PED_s to the second elements. Each of the second elements may be disposed on the first element associated with it. Specifically, the data mapping module 14 may map at least one classification name related to each process of the process sequence data PSD to a corresponding second element disposed on the first element for each process, based on the sorted process entry data PED_s.

For example, if a first classification name is related to the first process, which has the first priority in the process sequence data PSD, the data mapping module 14 may map the first classification name to the second element disposed on the first element corresponding to the first process with the first priority.

For example, if second and third classification names are related to the second process, which has a second priority in the process sequence data PSD, the data mapping module 14 may map the second and third classification names to the second elements disposed on the first element corresponding to the second process with the second priority, respectively.

In an embodiment, the data mapping module 14 may map the “N/A” value, which indicates no process history in the sorted process entry data PED_s, to the second element. For example, the data mapping module 14 may map the “N/A” value from the sorted process entry data PED_s to the second element on the first element corresponding to the process related to the “N/A” value.

In an embodiment, a plurality of second elements may be disposed on the same first element. In this case, the arrangement order or position of each of the second elements may be determined depending by user control or a predetermined algorithm.

In an embodiment, the arrangement order or position of each of the plurality of second elements disposed on the same first element may be changed based on user control or the predetermined algorithm.

The data mapping module 14 may map the plurality of process history data PHD, represented as classification names in the sorted process entry data PED_s, to coordinates within the second elements. As a result of this mapping, each coordinate may correspond to a wafer associated with each of the plurality of process history data PHD. In addition, each coordinate may include information about the start time point at which a process included in each of the plurality of process history data PHD is performed. The position of each coordinate in the second elements may be determined based on the start time information of the process included in each of the plurality of process history data PHD.

The second elements may include information about the time related to the processes in the process sequence data PSD. For example, the second elements, to which the process history data PHD are mapped as coordinates, may include the information on the start time of the process.

For example, some of the second elements, to which the plurality of process history data PHD are mapped as the coordinates, may include information on the execution sequence of processes for the plurality of wafers corresponding to the plurality of process history data PHD.

For example, some of the second elements, to which the plurality of process history data PHD are mapped as the coordinates, may include information on process execution intervals between the plurality of wafers corresponding to the plurality of process history data PHD.

The data mapping module 14 may connect the second elements for each wafer by using the third elements. For example, the data mapping module 14 may connect the coordinates mapped to the second elements for each wafer by using the third elements. In other words, each of the third elements may represent wafer-specific process flow information associated with the analysis target parameter ATP.

In an embodiment, the data mapping module 14 may generate a process flow table based on the wafer-specific process flow information associated with the analysis target parameter ATP.

In an embodiment, the third elements may be uniquely identified for each wafer. For example, the third elements may have a distinct color for each wafer or may be configured in different shapes.

The data analysis module 15 may receive the analysis data AD from the data mapping module 14 and analyze it to detect a suspected defective process. For example, the data analysis module 15 may detect a suspected defective process by analyzing time information or wafer-specific process flow information included in the analysis data AD.

In an embodiment, the data analysis module 15 may estimate the cause of a defect in the suspected defective process by comparing the analysis data AD associated with each distinct analysis target parameter ATP. For example, the data analysis module 15 may compare the first analysis data related to the first analysis target parameter with the second analysis data related to the second analysis target parameter. Based on this comparison, the data analysis module 15 may identify either the first or second analysis parameter as the likely cause of the defect in the suspected defective process.

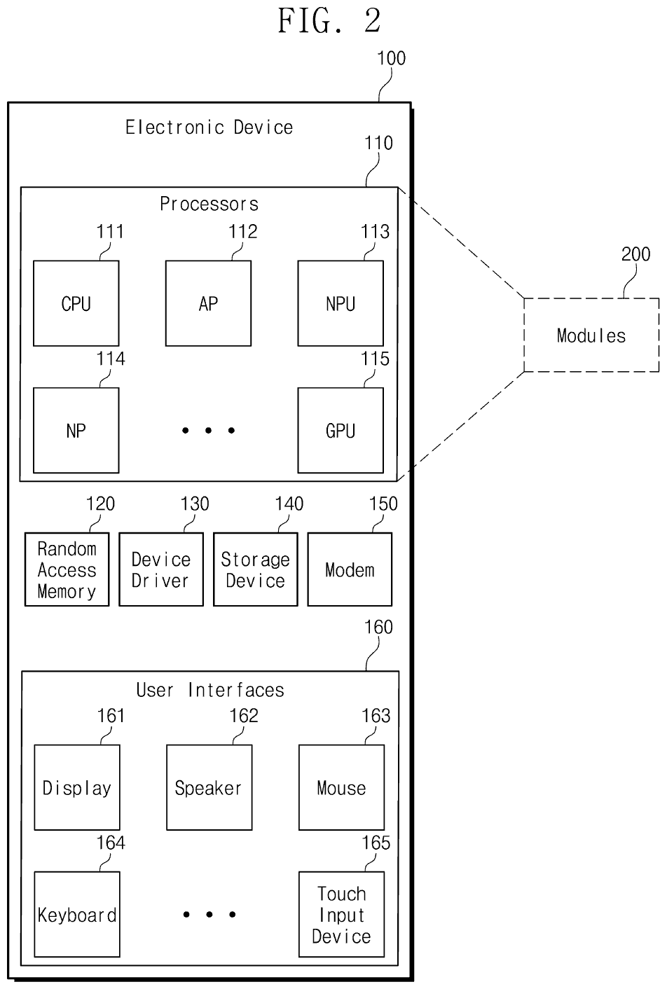

FIG. 2 is a block diagram illustrating an electronic device 100 according to an embodiment of the present disclosure. Referring to FIG. 2, the electronic device 100 may be configured to facilitate the analysis of the semiconductor process flow. The electronic device 100 may perform some of the functions or processes of the system 10 described with reference to FIG. 1. The electronic device 100 may include processors 110, a random access memory 120, a device driver 130, a storage device 140, a modem 150, and user interfaces 160.

The processors 110 may include at least one general purpose processor, such as a central processing unit (CPU) 111 or an application processor (AP) 112. The processors 110 may also include at least one special purpose processor, such as a neural processing unit (NPU) 113, a neuromorphic processor (NP) 114, or a graphic processing unit (GPU) 115. The processors 110 may include two or more processors of the same kind.

At least one processor among the processors 110 may execute modules 200. At least one processor among the processors 110 may execute the modules 200 based on various data or information. For example, the modules 200 may be implemented in the form of instructions (or codes) executed by at least one processor among the processors 110. In other words, the modules 200 may be implemented as instructions (or code) executed by at least one of the processors 110. In this case, at least one processor among the processors 110 may load the instructions (or codes) of the modules 200 into the random access memory 120.

As another example, at least one (or an additional) processor among the processors 110 may be designed to implement the modules 200. For example, this processor may be a dedicated processor implemented in hardware specifically to execute the functions of the modules 200.

As another example, at least one (or an additional) processor among the processors 110 may implement the modules 200 by receiving information (e.g., instructions or codes) corresponding to the modules 200.

The random access memory 120 may be used as an operation memory of the processors 110 and may be used as a main memory or a system memory of the electronic device 100. The random access memory 120 may include a volatile memory such as a dynamic random access memory or a static random access memory, or a nonvolatile memory such as a phase-change random access memory, a ferroelectric random access memory, a magnetic random access memory, or a resistive random access memory.

The device driver 130 may control peripheral devices such as the storage device 140, the modem 150, and the user interfaces 160, depending on a request from the processors 110. The storage device 140 may include a fixed storage device such as a hard disk drive, or a solid state drive, or a removable storage device such as an external hard disk drive, an external solid state drive, or a removable memory card.

The modem 150 may provide remote communication with an external device. The modem 150 may perform wireless or wired communication with the external device. The modem 150 may communicate with the external device through at least one of various types of communication such as Ethernet, Wi-Fi, LTE, and 5G mobile communication.

The user interfaces 160 may receive information from the user, such as settings of the analysis target parameter ATP, and provide output to the user, such as the analysis data AD. The user interfaces 160 may include at least one user output interface such as a display 161, or a speaker 162, and at least one user input interface such as a mouse 163, a keyboard 164, or a touch input device 165.

The instructions (or codes) of the modules 200 may be received through the modem 150 and stored in the storage device 140. The instructions (or codes) of the modules 200 may be stored in the removable storage device and coupled to the electronic device 100. The instructions (or codes) of the modules 200 may be loaded from the storage device 140 to the random access memory 120 and may be executed.

For example, the modules 200 may include at least one of the data extraction module 12, the data sorting module 13, the data mapping module 14, and the data analysis module 15, which are described with reference to FIG. 1. The data extraction module 12, the data sorting module 13, the data mapping module 14, and the data analysis module 15 may be implemented or executed in distinct electronic devices. Two or more modules of the data extraction module 12, the data sorting module 13, the data mapping module 14, and the data analysis module 15 may be implemented or executed in one electronic device. As an example, each of the data extraction module 12, the data sorting module 13, the data mapping module 14, and the data analysis module 15 may be implemented as an electronic circuit.

For example, the database 11 may be implemented as the storage device 140 as a component of the electronic device 100, or may be implemented as a remote device communicating with the electronic device 100 through the modem 150.

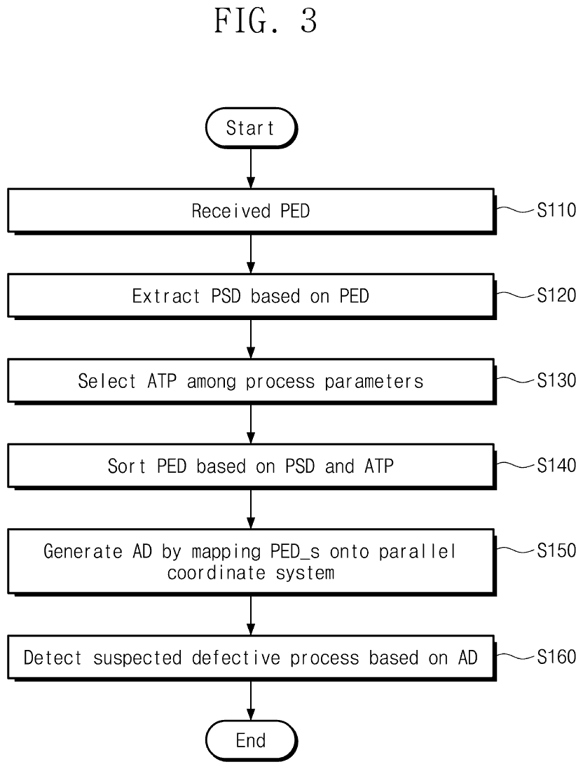

FIG. 3 illustrates an example of an operating method of the electronic device 100. Referring to FIG. 1 to FIG. 3, in operation S110, the electronic device 100 may receive the process entry data PED for the plurality of wafers. For example, the processors 110 of the electronic device 100 may receive the process entry data PED for the plurality of wafers from the database 11.

In operation S120, the electronic device 100 may extract the process sequence data PSD based on the process entry data PED. For example, the processors 110 of the electronic device 100 may extract the process sequence data PSD based on the process entry data PED.

In operation S130, the electronic device 100 may select the analysis target parameter ATP among the process parameters. For example, the processors 110 of the electronic device 100 may select one of the process parameters as the analysis target parameter ATP.

In operation S140, the electronic device 100 may sort the process entry data PED based on the process sequence data PSD and the analysis target parameter ATP. For example, the processors 110 of the electronic device 100 may sort the process entry data PED to ensure that the plurality of process history data PHD associated with the process entry data PED corresponds to each process in the process sequence data PSD for each wafer, based on the analysis target parameter ATP.

In operation S150, the electronic device 100 may generate the analysis data AD by mapping the sorted process entry data PED_s to the first coordinate system. For example, the processors 110 of the electronic device 100 may generate the analysis data AD by mapping the sorted process entry data PED_s to the parallel coordinate system. The analysis data AD may include time information associated with the processes in the process sequence data PSD or the sorted process entry data PED_s, as well as wafer-specific process flow information related to the parameters to be analyzed.

In operation S160, the electronic device 100 may identify the suspected defective process based on the analysis data AD. For example, the processors 110 of the electronic device 100 may detect the suspected defective process by analyzing the information included in the analysis data AD.

In an embodiment, the electronic device 100 may estimate the cause of the defect in the suspected defective process by comparing the analysis data AD corresponding to different analysis target parameters ATP. For example, the electronic device 100 may compare the first analysis data related to the first analysis target with the second analysis data related to the second analysis target. Based on this comparison, the electronic device 100 may estimate the cause of the defect in the suspected defective process.

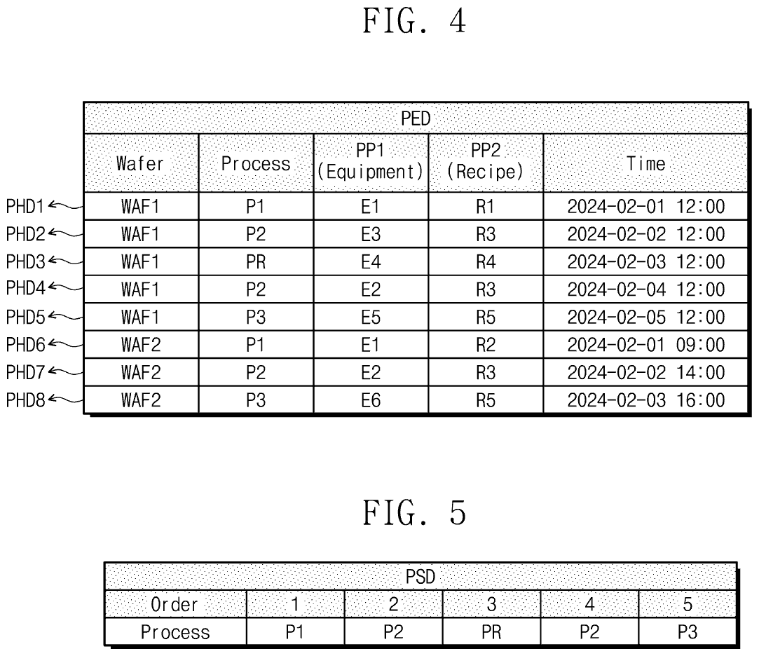

FIG. 4 illustrates an example of the process entry data PED according to an embodiment of the present disclosure. In FIG. 4, it is assumed that the process entry data PED includes first, second, third, fourth, fifth, sixth, seventh and eighth process history data PHD1, PHD2, PHD3, PHD4, PHD5, PHD6, PDH7 and PHD8 for first and second wafers WAF1 and WAF2, and first and second process parameters PP1 and PP2.

In FIG. 4, the first process parameter PP1 may represent the facility used in the process, and the second process parameter PP2 may represent the recipe applied to the process. Classification names for the first process parameter PP1 may range from first, second, third, fourth, fifth and sixth facilities E1, E2, E3, E4, E5 and E6 indicating the names of the facilities. Classification names of the second process parameter PP2 may range from first, second, third, fourth and fifth recipes R1, R2, R3, R4 and R5 indicating the names of the recipes. However, the scope of the present disclosure is not limited thereto.

Referring to FIG. 4, the process entry data PED may include the first to eighth process history data PHD1 to PHD8. Each of the first to eighth process history data PHD1 to PHD8 may include information about the wafer on which the process was performed, the type of the process performed, the classification name of the first process parameter PP1, the classification name of the second process parameter PP2, and the process execution start time point (also referred to as “start time”).

For example, the first process history data PHD1 indicates that the first process P1 using the first facility E1 and the first recipe R1 is performed on the first wafer WAF1. In this case, the process execution start time point is “2024-02-01, 12:00”.

For example, the second process history data PHD2 indicates that the second process P2 using the third facility E3 and the third recipe R3 is performed on the first wafer WAF1. In this case, the process execution start time point is “2024-02-02, 12:00”.

For example, the sixth process history data PHD6 indicates that the first process P1 using the first facility E1 and the second recipe R2 is performed on the second wafer WAF2. In this case, the process execution start time point is “2024-02-01, 09:00”.

Referring to the second to fourth process history data PHD2 to PHD4, after the second process P2 is performed on the first wafer WAF1, a restoration process PR is performed to return the first wafer WAF1 to a state of before the second process P2 is performed. After the restoration process PR is performed, the second process P2 is performed again on the first wafer WAF1. In other words, the restoration process PR is performed as indicated by the third process history data PHD3, and the second process P2 is performed again as indicated by the fourth process history data PHD4.

Referring to the sixth to eighth process history data PHD6 to PHD8, after the second process P2 is performed on the second wafer WAF2 as indicated by the seventh process history data PHD7, the third process P3 is performed as indicated by the eighth process history data PHD8. In other words, the restoration process PR is not performed on the second wafer WAF2, and the second process P2 is performed once.

FIG. 5 illustrates an example of the process sequence data PSD according to an embodiment of the present disclosure. Referring to FIG. 2, FIG. 4, and FIG. 5, the electronic device 100 may extract the process sequence data PSD that arranges all processes performed on the first and second wafers WAF1 and WAF2 in the order of their execution times, based on the process entry data PED.

In this case, referring to the second to fourth process history data PHD2 to PHD4 of FIG. 4, because the second process P2 is performed twice on the first wafer WAF1, the second process P2 may be listed twice in the process sequence data PSD. The process sequence data PSD may include the restoration process PR having a third priority (Order 3 in FIG. 5) arranged between the second process P2 having the second priority (Order 2 in FIG. 5) and the second process P2 having a fourth priority (Order 4 in FIG. 5). Accordingly, the process sequence data PSD may include the first process P1 having the first priority (Order 1 in FIG. 5), the second process P2 having the second priority (Order 2 in FIG. 5), the restoration process PR having the third priority (Order 3 in FIG. 5), the second process P2 having the fourth priority (Order 4 in FIG. 5), and the third process P3 having a fifth priority (Order 5 in FIG. 5).

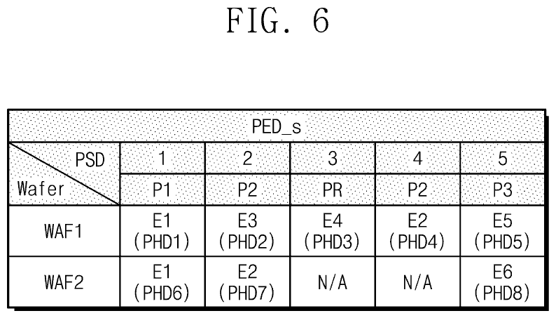

FIG. 6 illustrates an example of the sorted process entry data PED_s according to an embodiment of the present disclosure. Referring to FIG. 2, and FIG. 4 to FIG. 6, the electronic device 100 may select the first process parameter PP1 indicating the facility used in each process as the analysis target parameter ATP. The electronic device 100 may sort the first to eighth process history data PHD1 to PHD8 of the process entry data PED based on the first process parameter PP1 and the process sequence data PSD, which are the analysis target parameters ATP.

For example, the electronic device 100 may arrange each of the first to eighth process history data PHD1 to PHD8 in a field corresponding to each wafer and each process of the process sequence data PSD, based on the facility indicated by the first process parameter PP1. In the sorted process entry data PED_s, each of the first to eighth process history data PHD1 to PHD8 may be expressed as one of the first to sixth facilities E1 to E6, which are classification names of the first process parameter PP1. For example, in the sorted process entry data PED_s, the first process history data PHD1 is arranged in a field corresponding to the first process P1, which has the first priority, and the first wafer WAF1, and the value of the field may be the “first facility E1”. For example, in the sorted process entry data PED_s, the sixth process history data PHD6 is arranged in a field corresponding to the first process P1, which has the first priority, and the second wafer WAF2, and the value of the field may be the “first facility E1”. As another example, in the sorted process entry data PED_s, the fifth process history data PHD5 is arranged in a field corresponding to the fifth process P5, which has the fifth priority, and the first wafer WAF1, and the value of the field may be the “fifth facility E5”.

In the sorted process entry data PED_s, the field corresponding to the second wafer WAF2 and the restoration process PR with the third priority may have a value of “N/A” indicating that there is no process execution history.

The second process P2 is arranged twice in the process sequence data PSD and is performed once on the second wafer WAF2. In this case, the second wafer WAF2 and the seventh process history data PHD7 related to the second process P2 may be arranged to correspond to the second process P2 with the second priority, which is the highest priority among the second and fourth priorities of the second process P2 in the process sequence data PSD. In addition, the field value corresponding to the second wafer WAF2 and the second process P2 with the fourth priority may be “N/A” indicating that there is no process performance history.

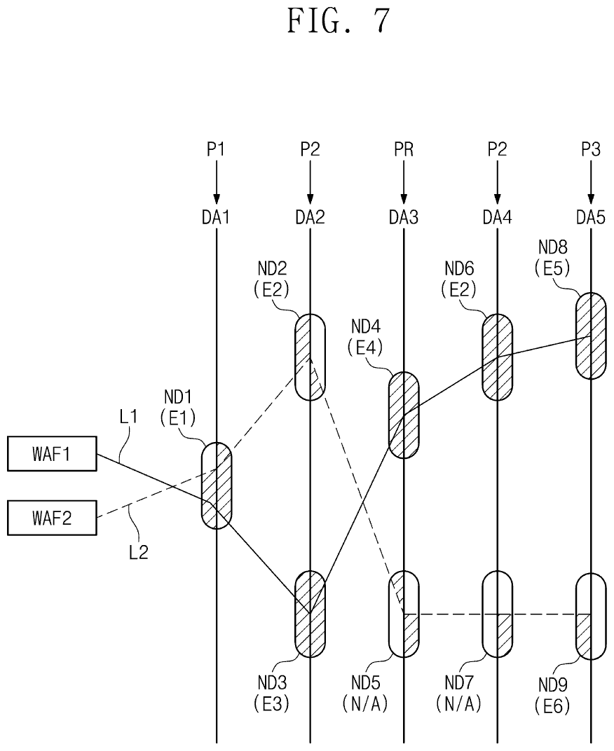

FIG. 7 illustrates an example of the analysis data AD according to an embodiment of the present disclosure. Referring to FIG. 2, and FIG. 4 to FIG. 7, the electronic device 100 may generate the analysis data AD by mapping the sorted process entry data PED_s to the parallel coordinate system. The analysis data AD may be simulation data.

The electronic device 100 may map processes P1, P2, PR, P2, and P3 from the process sequence data PSD to dimension axes based on the sorted process entry data PED_s. As a result of the mapping, the processes P1, P2, PR, P2, and P3 of the process sequence data PSD may correspond to their respective dimension axes.

For example, the first process P1 of the first priority may correspond to a first dimension axis DA1, the second process P2 of the second priority may correspond to a second dimension axis DA2, the restoration process PR of the third priority may correspond to a third dimension axis DA3, the second process P2 of the fourth priority may correspond to a fourth dimension axis DA4, and the third process P3 of the fifth priority may correspond to a fifth dimension axis DA5.

The electronic device 100 may map the first to sixth facilities E1 to E6 and “N/A” values, which are the classification names of the analysis target parameter ATP of the sorted process entry data PED_s, to first, second, third, fourth, fifth, sixth, seventh, eighth and ninth nodes ND1, ND2, ND3, ND4, ND5, ND6, ND7, ND8 and ND9. As a result of the mapping, the first to sixth facilities E1 to E6 and the “N/A” values may each correspond to one of the first to ninth nodes ND1 to ND9.

For example, the first node ND1 corresponds to the first facility E1 related to the first process P1 with the first priority, the second node ND2 corresponds to the second facility E2 related to the second process P2 with the second priority, the third node ND3 corresponds to the third facility E3 related to the second process P2 with the second priority, the fourth node ND4 corresponds to the fourth facility E4 related to the restoration process PR with the third priority, the fifth node ND5 corresponds to the “N/A” value related to the restoration process PR with the third priority, the sixth node ND6 corresponds to the second facility E2 related to the second process P2 with the fourth priority, the seventh node ND7 corresponds to the “N/A” value related to the second process P2 with the fourth priority, the eighth node ND8 corresponds to the fifth facility E5 related to the third process P3 with the fifth priority, and the ninth node ND9 corresponds to the sixth facility E6 related to the third process P3 with the fifth priority.

Each of the first to ninth nodes ND1 to ND9 may be positioned along a dimension axis corresponding to each of the first to ninth nodes ND1 to ND9 from among the first to fifth dimension axes DA1 to DA5.

For example, the first node ND1 may be disposed on the first dimension axis DA1, the second node ND2 and the third node ND3 may be disposed on the second dimension axis DA2, the fourth node ND4 and the fifth node ND5 may be disposed on the third dimension axis DA3, the sixth node ND6 and the seventh node ND7 may be disposed on the fourth dimension axis DA4, and the eighth node ND8 and the ninth node ND9 may be disposed on the fifth dimension axis DA5.

The electronic device 100 may map the first to eighth process history data PHD1 to PHD8, represented by the first to sixth facilities E1 to E6 in the sorted process entry data PED_s, to coordinates within the first to ninth nodes ND1 to ND9. As a result of the mapping, each coordinate may correspond to a wafer associated with each of the first to eighth process history data PHD1 to PHD8.

For example, the electronic device 100 may map the first process history data PHD1 to coordinates within the first node ND1, may map the second process history data PHD2 to coordinates within the third node ND3, may map the third process history data PHD3 to coordinates within the fourth node ND4, may map the fourth process history data PHD4 to coordinates within the sixth node ND6, and may map the fifth process history data PHD5 to coordinates within the eighth node ND8. The coordinates to which the first to fifth process history data PHD1 to PHD5 are mapped may correspond to the first wafer WAF1.

For example, the electronic device 100 may map the sixth process history data PHD6 to coordinates in the first node ND1, may map the seventh process history data PHD7 to coordinates in the second node ND2, and may map the eighth process history data PHD8 to coordinates in the ninth node ND9. The coordinates to which the sixth to eighth process history data PHD6 to PHD8 are mapped may correspond to the second wafer WAF2.

Both the fifth node ND5 and the seventh node ND7 may each include one coordinate corresponding to the second wafer WAF2.

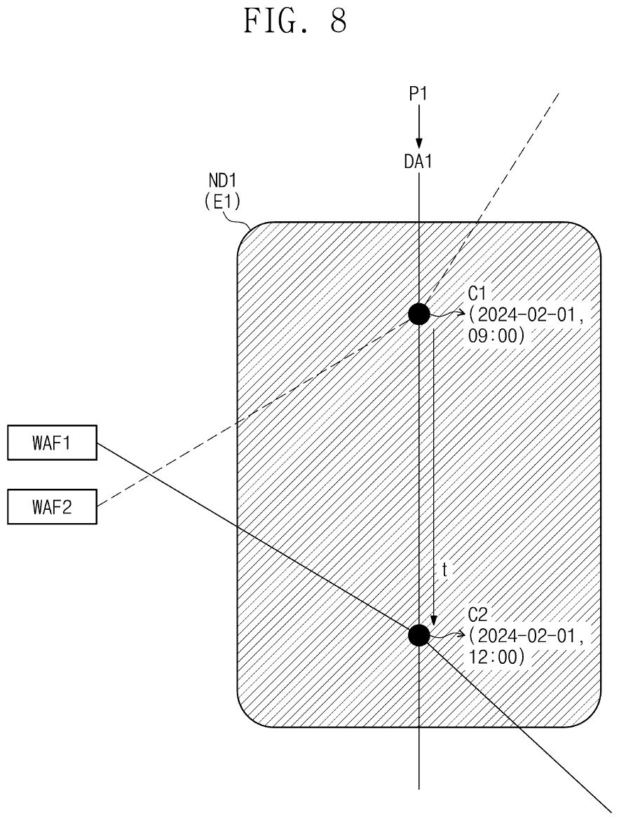

Nodes to which the first to eighth process history data PHD1 to PHD8 are mapped from among the first to ninth nodes ND1 to ND9 may include time information related to the processes P1, P2, PR, P2, and P3 of the process sequence data PSD. A detailed description thereof will be later with reference to FIG. 8.

In the analysis data AD, first and second connection lines L1 and L2 may connect the coordinates included in the nodes ND1 to ND9 for each wafer. The first and second connection lines L1 and L2 may represent wafer-specific process flow information related to the first process parameter PP1, which serves as the analysis target parameter ATP. For example, the first connection line L1 may represent the process flow information of the first wafer WAF1 associated with the first process parameter PP1, and the second connection line L2 may represent the process flow information of the second wafer WAF2 associated with the first process parameter PP1.

In an embodiment, the electronic device 100 may generate a process flow table that indicates wafer-specific process flow information based on the analysis data AD. For example, the electronic device 100 may generate the process flow table using the wafer-specific process flow information represented by the first and second connection lines L1 and L2.

TABLE 1
process flow table

| | | | | | |
|---|---|---|---|---|---|
| WAF1 | E1 | E3 | E4 | E2 | E5 |
| WAF2 | E1 | E2 | E6 | — | — |

Table 1 illustrates a process flow table based on the analysis data AD of FIG. 7. Referring to Table 1, the process flow table represents the process flow of each of the first and second wafers WAF1 and WAF2 based on the first to sixth facilities E1 to E6, which are the classification names of the analysis target parameters ATP. In other words, the process flow table may visualize the processes performed on each wafer using the classification names of the analysis target parameters ATP.

FIG. 8 illustrates the first node ND1 of FIG. 7 in detail. Referring to FIG. 2, and FIG. 4 to FIG. 8, the first node ND1 may include a first coordinates C1 corresponding to the second wafer WAF2 and a second coordinates C2 corresponding to the first wafer WAF1. The positions of the first and second coordinates C1 and C2 may be determined within a normalized time range based on the start time point of the first process P1 on the first and second wafers WAF1 and WAF2.

The first node ND1 may include the time information related to the first process P1. For example, the first node ND1 may include information about the start time points at which the first process P1 is performed on the first and second wafers WAF1 and WAF2.

For example, the first node ND1 may include information about the process execution sequence of the first and second wafers WAF1 and WAF2 for the first process P1 using the first facility E1. The information on the process execution sequence may be obtained from the start times at which the first process P1, as represented by in the first and second coordinates C1 and C2, is performed. In FIG. 8, “t” between the first and second coordinates C1 and C2 corresponds to time.

For example, the first node ND1 may include information on the process execution interval for the first and second wafers WAF1 and WAF2 during the first process P1 using the first facility E1. The information on the process execution interval may be obtained from the start times at which the first process P1, indicated by the first and second coordinates C1 and C2, is performed.

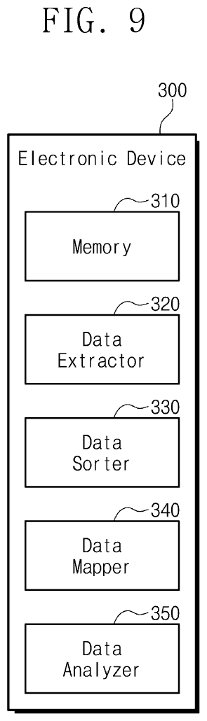

FIG. 9 is a block diagram illustrating an electronic device 300 according to an embodiment of the present disclosure. Referring to FIG. 9, the electronic device 300 may include a memory 310, a data extractor 320, a data sorter 330, a data mapper 340, and a data analyzer 350.

The memory 310 may store the process entry data PED for the plurality of wafers. For example, the memory 310 may store the process entry data PED including the plurality of process history data PHD.

The data extractor 320 may receive the process entry data PED from the memory 310. Based on the process entry data PED, the data extractor 320 may extract the process sequence data PSD, which arranges the processes performed on the plurality of wafers in the order of their execution times.

The data sorter 330 may receive the process entry data PED from the memory 310. The data sorter 330 may select the analysis target parameter ATP among the process parameters included in the process entry data PED.

The data sorter 330 may receive the process sequence data PSD from the data extractor 320. The data sorter 330 may sort the process entry data PED based on the analysis target parameter ATP and the process sequence data PSD. For example, the data sorter 330 may sort the plurality of process history data PHD of the process entry data PED for each wafer based on the analysis target parameter ATP and the process sequence data PSD.

The data mapper 340 may receive the sorted process entry data PED_s from the data sorter 330. The data mapper 340 may generate the analysis data AD by mapping the sorted process entry data PED_s to the parallel coordinate system.

The data analyzer 350 may receive the analysis data AD from the data mapper 340. The data analyzer 350 may detect the suspected defective process by analyzing the analysis data AD. For example, the data analyzer 350 may detect the suspected defective process by analyzing the time information or the wafer-specific process flow information included in the analysis data AD.

According to the present disclosure, an electronic device may simultaneously analyze process histories of a large quantity of wafers. The electronic device may analyze all processes performed on the plurality of wafers without any omissions. The electronic device may also analyze wafer-specific process flow information based on time data related to the processes carried out on the plurality of wafers. Accordingly, the electronic device can enhance the accuracy and efficiency of semiconductor process flow analysis.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An operating method for an electronic device including a processor for analyzing a semiconductor process flow, the method comprising:
receiving, at the processor, process entry data for a plurality of wafers;
extracting, at the processor, process sequence data that enumerates processes related to the plurality of wafers in order of execution times, based on the process entry data;
selecting, at the processor, an analysis target parameter from among process parameters included in the process entry data;
sorting, at the processor, the process entry data based on the process sequence data and the analysis target parameter; and
mapping, at the processor, the sorted process entry data to a parallel coordinate system to generate analysis data,
wherein the analysis data includes time information related to the processes in the process sequence data and wafer-specific process flow information corresponding to the analysis target parameter.

2. The method of claim 1, wherein the analysis data includes:
first elements corresponding to the processes in the process sequence data;
second elements disposed on the first elements, corresponding to names of the analysis target parameter, and including the time information; and
third elements that connect the second elements for each wafer,
wherein each of the second elements is related to at least one wafer among the plurality of wafers, and
wherein the third elements represent the wafer-specific process flow information.

3. The method of claim 2, wherein the time information includes an execution start time of each process in the process sequence data.

4. The method of claim 3, wherein at least some of the second elements include at least one coordinate related to the at least one wafer, and
wherein the at least one coordinate corresponds to the execution start time of a process performed on the at least one wafer.

5. The method of claim 2, wherein at least some of the second elements are related to at least two wafers among the plurality of wafers, and
wherein the time information includes a process performance interval between the at least two wafers.

6. The method of claim 2, wherein at least some of the second elements are related to at least two wafers among the plurality of wafers, and
wherein the time information includes a process execution sequence of the at least two wafers.

7. The method of claim 1, wherein the process sequence data include a first process and a second process that is performed after the first process, and
wherein the first process is identical to the second process.

8. The method of claim 7, wherein the process sequence data further include a third process that returns the wafer, on which the first process was performed, to its state prior to the first process, and
wherein the third process is listed between the first process and the second process in the process sequence data.

9. The method of claim 2, wherein at least some of the second elements correspond to a value indicating the absence of a process performance history.

10. An operating method for an electronic device including a processor for analyzing a semiconductor process flow, the method comprising:
receiving, at the processor, process entry data for a plurality of wafers, the process entry data include a first process, a second process and a third process, wherein the first process is performed before the second process, and the second process is performed before the third process;
extracting, at the processor, process sequence data indicating that the first process, the second process and the third process are performed sequentially, based on the process entry data;
selecting, at the processor, an analysis target parameter from among process parameters included in the process entry data;
sorting, at the processor, the process entry data based on the process sequence data and the analysis target parameter;
mapping, at the processor, the sorted process entry data to a parallel coordinate system to generate analysis data; and
detecting a suspected defective process based on the analysis data,
wherein the analysis data includes time information and wafer-specific process flow information, the time information is related to the first process, the second process and the third process, and the wafer-specific process flow information corresponds to the analysis target parameter.

11. The method of claim 10, wherein the analysis data includes:
first elements, each corresponding to the first process, the second process and the third process;
second elements disposed on the first elements, corresponding to names of the analysis target parameter, and including the time information; and
third elements that connected the second elements for each wafer,
wherein each of the second elements is associated with at least one wafer among the plurality of wafers, and
wherein the third elements represent the wafer-specific process flow information.

12. The method of claim 11, wherein the time information includes an execution start time of each of the first process, the second process and the third process.

13. The method of claim 12, wherein at least some of the second elements include at least one coordinate associated with the at least one wafer, and
wherein the at least one coordinate is associated with the execution start time of a process performed on the at least one wafer.

14. The method of claim 11, wherein at least some of the second elements are associated with at least two wafers of the plurality of wafers, and
wherein the time information includes a process performance interval between the at least two wafers.

15. The method of claim 11, wherein at least some of the second elements are associated with at least two wafers among the plurality of wafers, and
wherein the time information includes a process execution sequence of the at least two wafers.

16. The method of claim 10,
wherein the first process is identical to the third process.

17. The method of claim 16,
wherein the second process returns the wafer, on which the first process is performed, to its state prior to the first process.

18. The method of claim 11, wherein at least some of the second elements correspond to a value that indicates no process performance history.

19. An operating method for an electronic device for analyzing a semiconductor process flow, the method comprising:
extracting, at a data extractor, process sequence data that enumerates processes related to the plurality of wafers in order of execution times, based on the process entry data;
selecting, at a data sorter, an analysis target parameter from among process parameters included in the process entry data;
sorting, at the data sorter, the process entry data based on the process sequence data and the analysis target parameter; and
mapping, at a data mapper, the sorted process entry data to a parallel coordinate system to generate analysis data,
wherein the analysis data includes time information related to the processes in the process sequence data and wafer-specific process flow information corresponding to the analysis target parameter.

20. The method of claim 19, wherein the analysis data includes:
first elements corresponding to the processes in the process sequence data;
second elements disposed on the first elements, corresponding to names of the analysis target parameter, and including the time information; and
third elements that connect the second elements for each wafer,
wherein each of the second elements is related to at least one wafer among the plurality of wafers, and
wherein the third elements represent the wafer-specific process flow information.
